(19) United States
(12) Patent Application Publication
(10) Pub. No.: US 2010/0220440 A1
(43) Pub. Date: Sep. 2, 2010

(54) HEAT SINK AND MOTHERBOARD ASSEMBLY UTILIZING THE HEAT SINK

(75) Inventor: ZHENG-HENG SUN, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/479,694

(22) Filed: Jun. 5, 2009

(30) Foreign Application Priority Data
Feb. 27, 2009 (CN) 200910300609.X

(51) Int. Cl. G06F 1/20; H05K 7/20; F28F 21/08

(52) U.S. Cl. 361/679.54; 165/185

(57) ABSTRACT

A heat sink to dissipate heat for a motherboard includes a main body, and a fixing device. The main body includes a number of fins. The fixing device includes a fixing portion connected to a bottom of the main body, and two grounding pins extending from a bottom of the fixing portion, to engage in two idle grounding holes of the motherboard. A motherboard assembly utilizing the heat sink is also provided.

### CROSS-REFERENCE TO RELATED APPLICATION

The present application is related to a co-pending U.S. patent application (Attorney Docket No. US24164) filed on the same date and having the same title with the present application, which is assigned to the same assignee with this patent application.

### BACKGROUND

1. Technical Field

The present disclosure relates to a heat sink and, a motherboard assembly utilizing the heat sink.

2. Description of Related Art

An electronic device, such as a computer, usually includes a fan and a heat sink installed on a heat generating component of a motherboard for dissipating heat. However, some of the heat produced by the heat generating component will be transferred to the motherboard through pins of the heat generating component, which will lead to undesirable increase of the temperature of the motherboard.

### BRIEF DESCRIPTION OF THE DRAWINGS

FIG. 1 is an exploded, isometric view of a first embodiment of a heat sink together with a motherboard.

FIG. 2 is an assembled, isometric view of FIG. 1.

FIG. 3 is an exploded, isometric view of a second embodiment of a heat sink.

FIG. 4 is an exploded, isometric view of a third embodiment of a heat sink.

FIG. 5 is an exploded, isometric view of a fourth embodiment of a heat sink.

### DETAILED DESCRIPTION

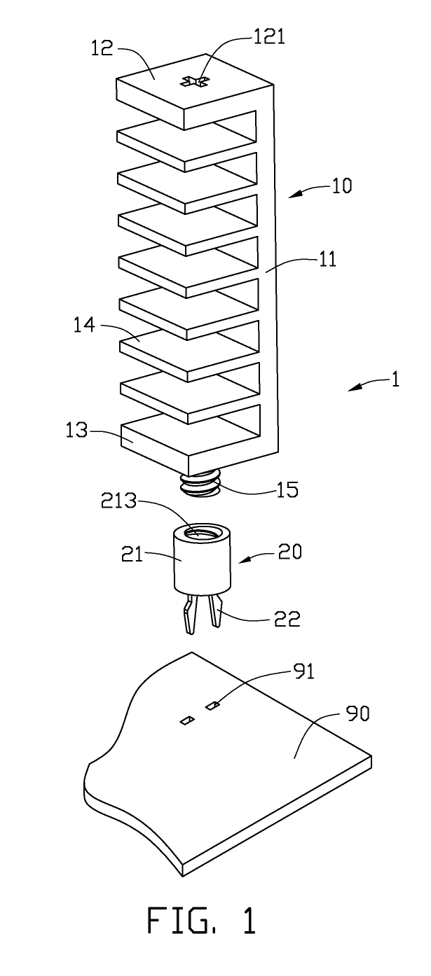

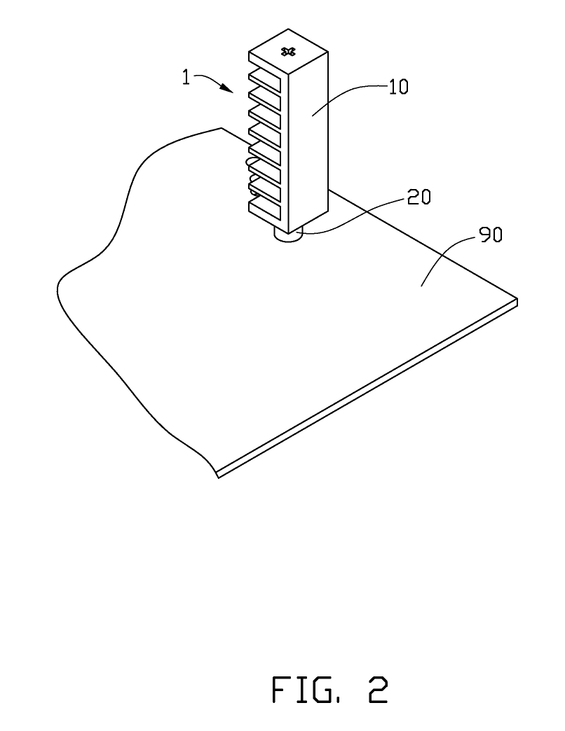

Referring to FIGS. 1 and 2, a heat sink 1 according to a first embodiment of the present disclosure is used for dissipating heat for a motherboard 90. The heat sink 1 includes a long slender main body 10, and a fixing device 20.

The main body 10 is integrally formed and includes an elongated supporting plate 11, a top plate 12 and a bottom plate 13 perpendicularly extending from the same side and opposite ends of the supporting plate 11, and a plurality of fins 14 perpendicularly extending from the supporting plate 11 and located between the top and bottom plates 12, 13 in parallel. An engaging recess 121 is defined in a top surface of the top plate 12. A threaded portion 15 perpendicularly extends from a bottom surface of the bottom plate 13.

The fixing device 20 is made of heat conducting material. The fixing device 20 includes a fixing portion 21, and two grounding pins 22 extending from a bottom of the fixing portion 21. A threaded hole 213 is defined in a top of the fixing portion 21. Structure of the grounding pins 22 is the same as that of grounding pins of a common connector, such as a serial connector, or a parallel connector.

To use the heat sink 1, the grounding pins 22 of the fixing device 20 are inserted into two corresponding idle grounding holes 91 defined in the motherboard 90, and then are fixed to the motherboard 90 through soldering. An assembly tool can be used to engage with the engaging recess 121 of the main body 10, to drive the main body 10 to rotate and make the threaded portion 15 engage in the threaded hole 213 of the fixing device 20. Thereby, the main body 10 is connected to the fixing device 20, and the assembled heat sink 1 is perpendicularly fixed to the motherboard 90. Because the heat sink 1 is slender, the heat sink 1 occupies little space and will not influence installation of other electronic components. Heat of the motherboard 90 is transferred to the main body 10 through the fixing device 20, and then is dissipated to the air through the plurality of fins 14 of the main body 10. Thereby, temperature of the motherboard 90 can be kept low.

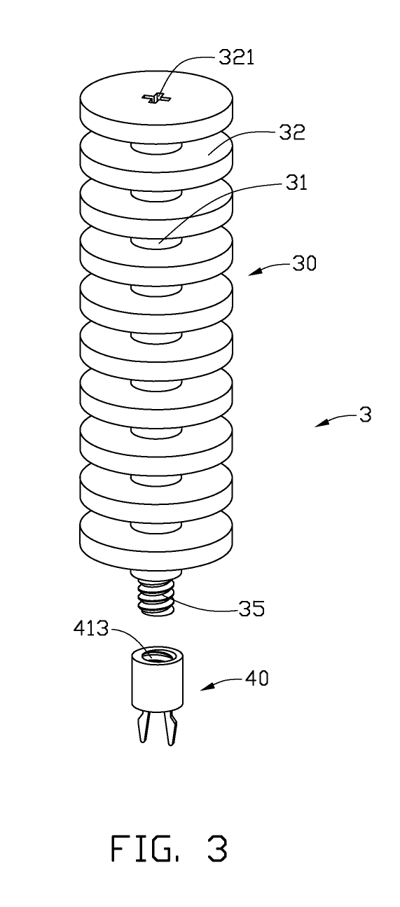

Referring to FIG. 3, a heat sink 3 according to a second embodiment of the present disclosure includes a slender columnar main body 30, and a fixing device 40. The fixing device 40 has the same structure as the fixing device 20 in the first embodiment. The main body 30 is integrally formed and includes a plurality of circular fins 32 in parallel, and a post 31 perpendicularly connecting middle sections of the plurality of fins 32. One of the fins 32 on the top of the main body 30 defines an engaging recess 321 in a top surface of the fin 32, and another one of the fins 32 on the bottom of the main body 30 forms a threaded portion 35. The threaded portion 35 is engagable with a threaded hole 413 defined in the fixing device 40.

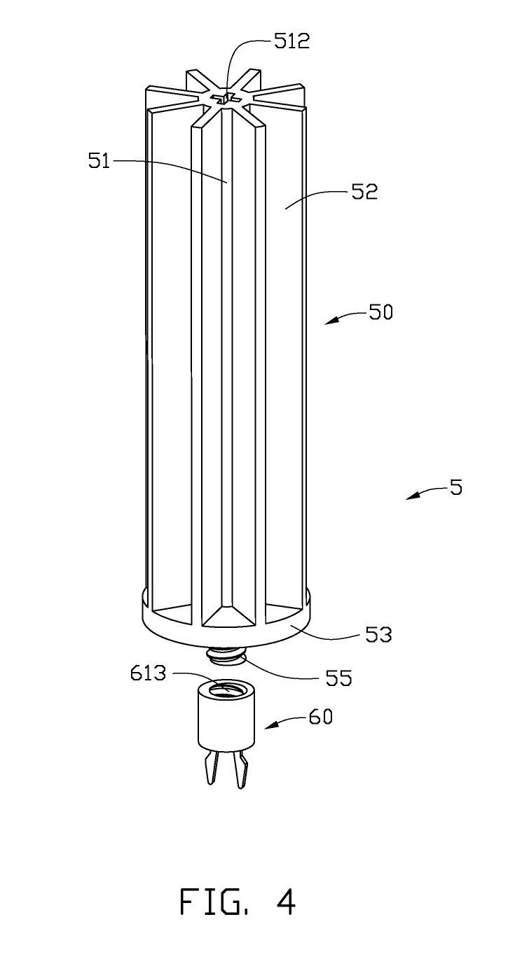

Referring to FIG. 4, a heat sink 5 according to a third embodiment of the present disclosure includes a slender columnar main body 50, and a fixing device 60. The fixing device 60 has the same structure as the fixing device 20 in the first embodiment. The main body 50 is integrally formed and includes a shaft 51, and a plurality of rectangular fins 52 radially extend out from a circumference of the shaft 51. The plurality of fins 52 is elongated along an axial direction of the shaft 51. Bottom surfaces of the fins 52 and a bottom surface of the shaft 51 are connected to a bottom plate 53. A threaded portion 55 perpendicularly extends from a bottom surface of the bottom plate 53, which is engagable with a threaded hole 613 of the fixing device 60.

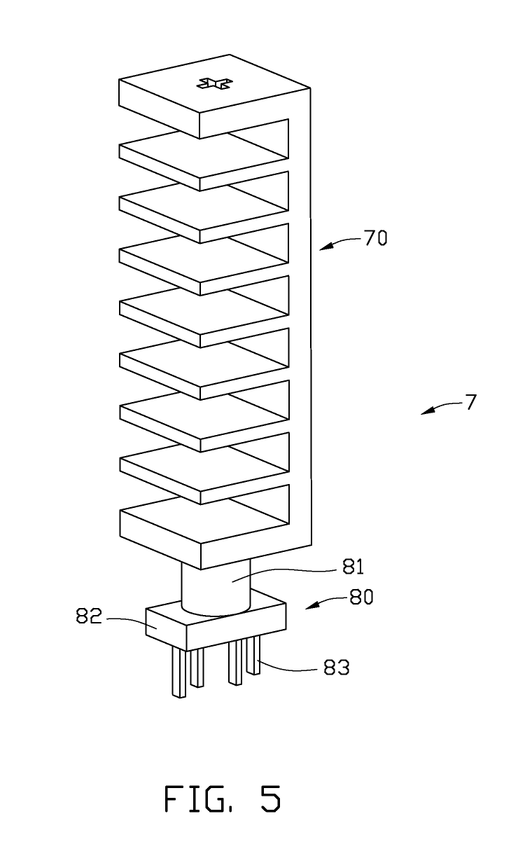

Referring to FIG. 5, a heat sink 7 according to a fourth embodiment of the present disclosure includes a slender main body 70, and a fixing device 80. The main body 70 has the same structure as the main body 10 in the first embodiment. The fixing device 80 includes a fixing portion 81 connected to the main body 70, a rectangular base 82 formed on a bottom of the fixing portion 81, and four grounding pins 83 extending from a bottom of the base 82. Structure of the grounding pins 83 is the same as that of grounding pins of a peripheral component interconnection card connector and a peripheral component interconnection-express card connector, thereby, the grounding pins 83 of the heat sink 7 can be inserted into four corresponding idle grounding holes on a motherboard.

It is to be understood, however, that even though numerous characteristics and advantages of the present disclosure have been set forth in the foregoing description, together with details of the structure and function of the disclosure, the disclosure is illustrative only, and changes may be made in details, especially in matters of shape, size, and arrangement of parts within the principles of the disclosure to the full extent indicated by the broad general meaning of the terms in which the appended claims are expressed.

What is claimed is:

1. A heat sink to dissipate heat for a motherboard, the heat sink comprising:
a main body comprising a plurality of fins; and
a fixing device comprising a fixing portion connected to a bottom of the main body, and at least two grounding pins extending from a bottom of the fixing portion, to engage in at least two idle grounding holes of the motherboard.

2. The heat sink of claim 1, wherein the main body is slender.

3. The heat sink of claim 2, wherein the main body further comprises an elongated supporting plate, a top plate and a bottom plate perpendicularly extending from opposite ends of the supporting plate, wherein the plurality of fins are perpendicularly formed on the supporting plate and between the top plate and the bottom plate.

4. The heat sink of claim 2, wherein the main body is columnar and further comprises a post, wherein the post are connected to middles of the plurality of fins that are arranged in parallel.

5. The heat sink of claim 2, wherein the main body is columnar and further comprises a shaft, the plurality of fins radially extend from a circumference of the shaft, and the plurality of fins are elongated along an axial direction of the shaft.

6. The heat sink of claim 1, wherein a threaded portion perpendicularly extends from a bottom of the main body, a threaded hole is defined in a top of the fixing device to engage with the threaded portion.

7. The heat sink of claim 1, wherein an engaging recess is defined in a top of the main body.

8. The heat sink of claim 1, wherein structure of the grounding pins is the same as that of grounding pins of a serial connector or a parallel connector.

9. The heat sink of claim 1, wherein structure of the grounding pins is the same as that of grounding pins of a peripheral component interconnection card connector or a peripheral component interconnection-express card connector.

10. The heat sink of claim 1, wherein the fixing device is made of heat conducting material.

11. A motherboard assembly comprising:
a motherboard defining at least two idle grounding holes; and
a heat sink comprising a main body and a fixing device connected to the main body, the main body comprising a plurality of fins, the fixing device being made of heat conducting material and comprising at least two grounding pins engaging in the corresponding idle grounding holes of the motherboard, to transfer heat from the motherboard to the main body.

12. The motherboard assembly of claim 11, wherein the main body is slender and perpendicularly fixed to the motherboard, the main body further comprises an elongated supporting plate, a top plate and a bottom plate perpendicularly extending from the supporting plate, wherein the plurality of fins are perpendicularly formed on the supporting plate and between the top plate and the bottom plate.

13. The motherboard assembly of claim 11, wherein the main body is columnar and slender, and perpendicularly fixed to the motherboard, the main body further comprises a post, the plurality of fins are circular and are arranged in parallel, the post perpendicularly connects middle sections of the plurality of fins.

14. The motherboard assembly of claim 11, wherein the main body is slender and perpendicularly fixed to the motherboard, the main body further comprises a shaft, the plurality of fins radially extend from a circumference of the shaft, and the plurality of fins are elongated along an axial direction of the shaft.

15. The motherboard assembly of claim 11, wherein an engaging recess is defined in a top of the main body.

16. The motherboard assembly of claim 11, wherein structure of the at least two grounding pins is the same as that of grounding pins of a serial connector or a parallel connector.

17. The motherboard assembly of claim 11, wherein structure of the at least two grounding pins is the same as that of grounding pins of a peripheral component interconnection (PCI) card connector or a PCI express card connector.
